(19) United States
(12) Patent Application Publication
(10) Pub. No.: US 2025/0226213 A1
(43) Pub. Date: Jul. 10, 2025

(54) ISOTROPIC THERMAL ATOMIC LAYER ETCH OF ZIRCONIUM AND HAFNIUM OXIDES

(71) Applicant: Merck Patent GmbH, Darmstadt (DE)

(72) Inventors: Martin E. McBRIARTY, San Jose, CA (US); Bhushan ZOPE, San Jose, CA (US); Lanxia CHENG, San Jose, CA (US); Son HOANG, San Jose, CA (US)

(21) Appl. No.: 18/703,127

(22) PCT Filed: Dec. 15, 2022
(86) PCT No.: PCT/EP2022/086070

§ 371 Date: Apr. 19, 2024

Related U.S. Application Data
(60) Provisional application No. 63/290,762, filed on Dec. 17, 2021.

(51) Int. Cl. H01L 21/02; H10D 1/00; H10D 1/68

(52) U.S. Cl. CPC H01L 21/02337; H01L 21/02181; H01L 21/02189; H10D 1/041; H10D 1/68

(57) ABSTRACT

The disclosed and claimed subject matter relates to (1) a process for performing thermal atomic layer etching (ALE) of films that include ZrO₂, HfO₂, (Hf—Zr)O₂ alloy or similar materials which does not require the use of plasmas or corrosive halogenating chemistries and (2) a metal-insulator-metal capacitor (MIMcap) with unique properties enabled by a unique dielectric processing method.

### BACKGROUND

### Field

The disclosed and claimed subject matter relates to a process for performing thermal atomic layer etching (ALE) of films that include ZrO₂, HfO₂, (Hf—Zr)O₂ alloy or similar materials which does not involve the use of plasmas or corrosive halogenating chemistries. The disclosed and claimed subject matter further includes a metal-insulator-metal capacitor (MIMcap) with unique properties enabled by a unique dielectric processing method that includes the steps of (i) growing a film of ZrO₂, HfO₂ or (Hf—Zr)O₂ alloy, which is thicker than the final desired thickness, (ii) thermally treating the film to achieve desirable properties (e.g., high k, low leakage, and/or ferroelectricity); and (iii) isotropic ALE to remove a portion of the thickness of the film where the resulting thinned film retains the desirable properties of the initially grown (i.e., thicker) film.

### Related Art

The miniaturization of features in the semiconductor industry is the main factor behind the continuous performance increase of devices. This trend is expected to continue for at least a few more generations of computer chips. In this regard, ultrathin (<5 nm) layers of high k dielectrics are needed for volatile and non-volatile memories, including DRAM, NAND Flash, and ferroelectric memories. Several technical challenges need to be successfully solved for this trend to continue.

Atomic Layer Deposition (ALD) is one technique finding increased application in the semiconductor industry and it currently is the deposition method allowing the best control on the amount of material deposited. In ALD, a layer of atoms is deposited on all surfaces that are exposed to a precursor in the gas phase—this layer is at most as thick as the thickness of one atomic layer. By sequentially exposing the surfaces to two different precursors, a layer of material with the desired thickness will be deposited. The archetypical example of such a process is the deposition of aluminum oxide (Al₂O₃) from trimethylaluminum (TMA, Al(CH₃)₃) and water (H₂O), where methane (CH₄) is eliminated from the two reacting species. The coating of thin and narrow vias and other high aspect ratio features have been demonstrated numerous times by ALD in the literature.

Atomic Layer Etching (ALE or ALEt) can be viewed as the layer-by-layer subtraction of material when ALD is the layer-by-layer addition of material. In ALE, a layer of atoms is removed from all surfaces that are exposed to a precursor in the gas phase—this layer is ideally also at most as thick as the thickness of one atomic layer. ALE is performed by sequentially exposing the surfaces to at least two different precursors, a 1^{st} precursor that activates a layer of surface atoms and a 2^{nd} precursor that promotes the sublimation of this activated layer of atoms; sometimes a 3^{rd} precursor is used to regenerate the surface to the condition where the 1^{st} precursor will be active.

For example, an early copper etching process was described in which copper was chlorinated using a plasma to generate CuCl₂. See, e.g., Tamirisa et al., Microelectron., 84, 1055 (2007); Wu et al., J. Electrochem. Soc., 157, H474 (2010) and Hess D. W., Workshop on Atomic-Layer-Etch and Clean Technology, San Francisco, Ca (2014). The CuCl₂ layer was then etched with a hydrogen plasma, which generated volatile Cu₃Cl₃. This process could be performed at temperatures as low as 20° C. However, the usefulness of this process for etching copper in small features was limited because of significant profile taper.

Another method involved the etching of tungsten. See, e.g., Johnson N. R. and George S. M., ACS Applied Materials & Interfaces, 9, 34435 (2017). In this process, and as illustrated in FIG. 1, tungsten could be etched (between 128° C. and 207° C.) by sequentially exposing a tungsten surface having a native oxide layer to:
(A) A mixture of oxygen and ozone, which oxidizes an additional layer of tungsten into tungsten oxide (surface activation);
(B) Boron trichloride, which reacts with some of the tungsten oxide to generate non-volatile boron oxide and volatile tungsten oxychloride (sublimation of tungsten-containing species; some tungsten oxide is still present below the boron oxide); and
(C) Hydrogen fluoride, which react with the boron oxide to generate volatile water vapor, and volatile boron trifluoride (regeneration of fresh tungsten oxide surface).

Another method is related to the etching of cobalt. See, e.g., Chen et al., J. Vac. Sci. Technol., A 35, 05C305 (2017). In this method, cobalt etching, at temperatures higher than 80° C., was achieved with an etching rate was as high as 28 Å/cycle and was far from being self-limiting. This process involved the sequential exposure of a cobalt surface to:
(A) An oxygen plasma which oxidizes multiple layers of cobalt into cobalt oxide (surface activation); and
(B) Formic acid, which react with the cobalt oxide surface species to generate volatile cobalt formate species (sublimation).

An alternative method was used to etch cobalt and copper thin films by using supercritical CO₂ and 1,1,1,5,5,5-hexafluoro-2,4,-pentanedione at 100° C. and 250° C. under high-pressure. See, e.g., Rasadujjaman et al., Microelectron. Eng. 153, 5 (2016).

Another reported method involved etching copper at temperatures higher than 275° C. with an etch rate of 0.09 nm/cycle. See, e.g., Mohimi et al., ECS Journal of Solid State Science and Technology, 7, P491 (2018). This process involved the sequential exposure of a copper surface to:
(A) oxygen which is a mild oxidizer and oxidizes a layer of copper into copper oxide (surface activation); and
(B) an acetylacetone (such as 1,1,1,5,5,5-hexafluoro-2,4,-pentanedione (HFAC), which reacts with the copper oxide surface species to generate volatile copper acetylacetonate species (sublimation).

Several cobalt etching procedures have also been described. See, e.g., Zhao et al., Applied Surface Science, 455, 438 (2018) and Konh et al., Journal of Vacuum Science & Technology A, 37, 021004 (2019). In one of these procedures, cobalt was etched at temperatures higher than 377° C. and exposing the cobalt surface (with a native oxide) to 1,1,1,5,5,5-hexafluoro-2,4,- pentanedione (HFAC). The treated surface was then heated to produce sublimation of cobalt 1,1,1,5,5,5-hexafluoro-2,4,-pentanedionate. In a variant, cobalt was etched at temperatures higher than 140° C. by sequentially exposing the cobalt surface to:
(A) chlorine which oxidizes a layer of cobalt into cobalt chloride (surface activation); and
(B) an acetylacetone (such as 1,1,1,5,5,5-hexafluoro-2,4,-pentanedione (HFAC), which react with the cobalt chloride surface species to generate volatile cobalt chloro-acetylacetonate species (sublimation).

Methods have been described for the thermal ALE of oxides, including ZrO₂, HfO₂, Al₂O₃, and TiO₂. See, e.g., Y. Lee, C. Huffman, and S. M. George, Chem. Mater. 28 (2016) 7657-7665; P. C. Lemaire and G. N. Parsons, Chem. Mater., 29 (2017) 6653-6665; J. A. Murdzek and S. M. George, J. Vac. Sci. Technol. A 38 (2020) 022608; H. Saare, PhD dissertation, North Carolina State U., 2021. These methods typically involve two steps which are cycled: a fluoridation of the oxide surface in a first step, and a volatilization of the resulting surface fluoride in a second step. For the first step, fluoridating agents include hydrogen fluoride (HF), anhydrous hydrogen fluoride stabilized by pyridine (HF-pyridine), sulfur tetrafluoride (SF₄), sulfur hexafluoride (SF₆) remote plasma, tungsten hexafluoride (WF₆), or xenon difluoride (XeF₂). For the second step, volatilization agents include trimethylaluminum (TMA), dimethylaluminum chloride (DMAC), silicon tetrachloride (SiCl₄), or titanium tetrachloride (TiCl₄).

A method of thermal ALE of Al₂O₃, ZrO₂, HfZrO₄ and HfO₂ was described by Lee et al. (Y. Lee, C. Huffman, and S. M. George, Chem. Mater. 28, 7657-7665 (2016)) and Murdzek and George (J. A. Murdzek and S. M. George, J. Vac. Sci. Technol. A 38, 022608 (2020)).

In Lee, Huffman, and George, ALE testing was conducted at process temperatures ranging from 150° C. to 350° C. These metal oxides were all effectively fluorinated using anhydrous HF delivered from an ampule of HF-pyridine. Al₂O₃ could be etched by cycling doses of anhydrous HF and either tin (ii) acetylacetonate Sn(acac)₂, trimethylaluminum (TMA), dimethylaluminum chloride (DMAC), or silicon tetrachloride (SiCl₄). ZrO₂ could be etched by cycling doses of anhydrous HF and either Sn (acac)₂, DMAC, or SiCl₄. HfO₂ could be etched by cycling doses of anhydrous HF and either Sn (acac)₂, TMA, or DMAC.

In Murdzek and George, ALE testing was conducted at a process temperature of 250° C. HF, SF₄, and XeF₂ were used as fluorinating agents, and DMAC and TiCl₄ were used as ligand exchange agents. For all tested chemistries, crystalline ZrO₂, HfZrO₄, and HfO₂ etched at a lower rate than amorphous ZrO₂, HfZrO₄, and HfO₂, respectively. XeF₂ was found to yield a much higher etch per cycle than HF or SF₄.

A method of thermal ALE of TiO₂ and ZrO₂ was described by Lemaire and Parsons (P. C. Lemaire and G. N. Parsons, Chem. Mater., 29, 6653-6665 (2017)) and Saare (H. Saare, PhD dissertation, North Carolina State U., (2021)). In Lemaire and Parsons, ALE testing was conducted at process temperatures ranging from 120° C. to 220° C. WF₆ was used as the fluorinating agent, and BCl₃ was used as the ligand-exchange agent. While the process yielded ALE of TiO₂, residues of B or W remained on the surface. In Saare, ALE testing was conducted at process temperatures ranging from 160° C. to 325° C. WF₆ was used as the fluorinating agent, and BCl₃, TiCl₄, and SOCl₂ were used as ligand-exchange agents. Each ALE process yielded ALE of TiO₂ and ZrO₂.

Few-nanometer films of ZrO₂ and HfO₂ have different functional properties based on the thickness and crystal structure of the film. The high-k tetragonal crystal phase of ZrO₂, or the ferroelectric crystal phase of Hf_{0.5}Zr_{0.5}O₂, can only be stabilized above a certain minimum thickness of film, approx. 5 to 7 nm. If a thinner film than 5 to 7 nm is desired (e.g., to maximize capacitance and/or reduce the device size), then a thicker film must first be grown and processed (i.e., to crystallize the film), followed by the removal of some of the film material. Such a material removal method requires sub-nanometer precision, and the removal may need to be isotropic (e.g., for conformally etching high aspect ratio features in 3D nano-architectures such as DRAM capacitors or 3D memory stacks). The best approach for this is isotropic atomic layer etching (ALE).

As noted above, isotropic ALE involves repeated cycles of dosing a reactant into a chamber, then purging the chamber to remove an excess of the reactant and any reaction products. In some implementations, there are two sequential dose-purge sub-cycles, each with a different reactant or combination of reactants. In some implementations, there are three or more sequential dose-purge sub-cycles, each with a different reactant or combination of reactants.

All the processes described above permit etching of metals while either using an oxygen plasma or halogen-containing reactants. However, plasmas can be destructive to substrates and many halogens can lead to contamination. Thus, new etching reagents-such as those (tungsten hexafluoride, WF₆) used in the disclosed and claimed subject matter-do not require a plasma, and do not contain corrosive halogens. Accordingly, a process free of plasmas or directed ions is highly desirable.

Although HF is prevalently used in ALE processing, its highly corrosive and toxic nature makes it difficult to handle safely. In addition, since HF is a highly polar molecule, it tends to stick to the inner walls of the reactor chamber during processing, so long extended purge times are needed to ensure elimination. See, e.g., Xie et al., J. Vac. Sci. Technol. A, 022605 (2020). Therefore, ALE processes that do not rely on HF are highly advantageous for implementation.

### SUMMARY

In one aspect, the disclosed and claimed subject matter relates to processes for the isotropic thermal ALE of metal oxides, including ZrO₂, HfO₂, HfₓZr₁₋ₓO₂ where x is a value between 0 and 1, including but not limited to 0.5, and other materials based on ZrO₂ and HfO₂ with engineered impurities or dopants, TiO₂, Al₂O₃ and combinations thereof. The processes include, consist essentially of or consist of the steps of (i) a first surface modification comprising exposing the surface of the metal oxide substrate to one or more fluorinating agent to produce a fluorinated surface, (ii) a first purge, (iii) a ligand-exchange comprising exposing the fluorinated surface to one or more chlorine ligand-supplying agent to produce a volatile chlorinated species, (iv) a second purge, (v) a second surface modification comprising exposing the surface of the metal oxide substrate to one or more oxidants to oxidize metal byproducts and (vi) a third purge. The steps in the processes can be cycled as many times as needed to remove a desired thickness of metal oxide. An optional step (vii) post-treatment may be added to remove impurities remaining on the surface following a number of cycles.

In another aspect, the disclosed and claimed subject matter relates to a metal-insulator-metal capacitor (“MIMcap”) device made using the disclosed and claimed ALE processes. In a further aspect, the MIMcap devices ideally demonstrate a higher dielectric constant (k) and lower leakage current than an otherwise equivalent MIMcap made without using the disclosed and claimed ALE processes.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an exemplary cycle of the disclosed and claimed ALE process utilizing ZrO2, WF6, DMAC and an oxidant.

### DEFINITIONS

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M. et al. J. Phys. Chem., 100, 13121-13131 (1996). In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, Chapter 1, pp. 1-36 (2009).

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The disclosed and claimed precursors are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably less than 100 ppm measured by proton NMR or Karl Fischer titration.

The disclosed and claimed precursors are also preferably substantially free of unintended presence of metal ions or metals such as, Li⁺ (Li), Na⁺ (Na), K⁺ (K), Mg²⁺ (Mg), Ca²⁺ (Ca), Al³⁺ (Al), Fe²⁺ (Fe), Fe³⁺ (Fe), Ni²⁺ (Ni), Cr³⁺ (Cr), titanium (Ti), vanadium (V), manganese (Mn), cobalt (Co), nickel (Ni), copper (Cu) or zinc (Zn). These metal ions or metals are potentially present from the starting materials/reactor employed to synthesize the precursors. As used herein, the term “substantially free” as it relates to the unintended presence of Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS.

Unless otherwise indicated, “alkyl” refers to a C₁ to C₂₀ hydrocarbon group which can be linear, branched (e.g., methyl, ethyl, propyl, isopropyl, tert-butyl and the like) or cyclic (e.g., cyclohexyl, cyclopropyl, cyclopentyl and the like). These alkyl moieties may be substituted or unsubstituted as described below. The term “alkyl” refers to such moieties with C₁ to C₂₀ carbons. It is understood that for structural reasons linear alkyls start with C₁, while branched alkyls and cyclic alkyls start with C₃. Moreover, it is further understood that moieties derived from alkyls described below, such as alkyloxy and perfluoroalkyl, have the same carbon number ranges unless otherwise indicated. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Halo or halide refers to a halogen, F, Cl, Br or I which is linked by one bond to an organic moiety. In some embodiments, the halogen is F. In other embodiments, the halogen is Cl.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt. % or higher, more preferably 99 wt. % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As noted above, the disclosed and claimed subject matter relates to processes for the isotropic thermal ALE of metal oxides, including ZrO₂, HfO₂, HfₓZr₁₋ₓO₂ where x is a value between 0 and 1, and other materials based on ZrO₂ and HfO₂ with engineered impurities or dopants, TiO₂, Al₂O₃ and combinations thereof. The processes include, consist essentially of or consist of the steps of:
(i) a first surface modification comprising exposing the surface of the metal oxide substrate to one or more fluorinating agent to produce a fluorinated surface;
(ii) a first purge;
(iii) a ligand-exchange comprising exposing the fluorinated surface to one or more chlorine ligand-supplying agent to produce a volatile chlorinated species;
(iv) a second purge;
(v) a second surface modification comprising exposing the surface of the metal oxide substrate to one or more oxidants to oxidize metal byproducts; and
(vi) a third purge.
   In a further aspect of this embodiment, the method consists essentially of steps (i), (ii), (iii), (iv), (v) and (vi). In a further aspect of this embodiment, the method consists of steps (i), (ii), (iii), (iv), (v) and (vi). The steps in the processes can be cycled as many times as needed to remove a desired thickness of metal oxide. In a further aspect, any of the forgoing embodiments can further include a step (vii) post-treatment may be added to remove impurities remaining on the surface following a number of cycles. In this case, the method includes, consists essentially of or consists of steps (i), (ii), (iii), (iv), (v), (vi) and (vii).

### Number of Cycles

As noted above, in the disclosed and claimed ALE processes, the steps can be cycled as many times as needed to remove a desired thickness of metal oxide. In the above-described embodiments, as well as the other embodiments described herein, the described steps define one cycle of the process. As those skilled in the art will understand (and as noted above), the disclosed and claimed process will include a purge step (ii) when proceeding from step (i) to step (iii), a purge step (iv) when proceeding from step (iii) to step (v) as well as an additional purge step (vi) before beginning a new cycle (i.e., proceeding from step (v) to step (i)). However, purge steps do not have to be performed between iterations of a single step (e.g., between multiple iterations of step (i), between multiple iterations of step (iii) or between multiple iterations of step (v)). Thus, a single cycle is to be understood as beginning when the first iteration of step (i) is performed and ending when the last purge step (vi) is performed before another iteration of step (i) is performed again regardless of the number of purging steps conducted during the process. It is to be understood that a cycle can be repeated until the desired thickness of a film is obtained.

In one embodiment, the number of cycles is from about 100 to about 1000. In one embodiment, the number of cycles is from about 20 to about 250. In one embodiment, the number of cycles is from about 10 to about 150. In one embodiment, the number of cycles is from about 5 to about 100. In one embodiment, the number of cycles is from about 5 to about 75. In one embodiment, the number of cycles is from about 5 to about 50. In one embodiment, the number of cycles is from about 5 to about 30. In one embodiment, the number of cycles is from about 5 to about 20. In one embodiment, the number of cycles is from about 15 to about 400. In one embodiment, the number of cycles is from about 20 to about 300. In one embodiment, the number of cycles is from about 25 to about 250. In one embodiment, the number of cycles is from about 35 to about 200. In one embodiment, the number of cycles is from about 45 to about 170. In one embodiment, the number of cycles is from about 50 to about 150. In one embodiment, the number of cycles is from about 75 to about 125. In one embodiment, the number of cycles is from about 25 to about 100. In one embodiment, the number of cycles is from about 50 to about 100. In one embodiment, the number of cycles is from about 75 to about 100.

In one embodiment, the number of cycles is about 5. In one embodiment, the number of cycles is about 10. In one embodiment, the number of cycles is about 15. In one embodiment, the number of cycles is about 20. In one embodiment, the number of cycles is about 25. In one embodiment, the number of cycles is about 30. In one embodiment, the number of cycles is about 35. In one embodiment, the number of cycles is about 40. In one embodiment, the number of cycles is about 45. In one embodiment, the number of cycles is about 50. In one embodiment, the number of cycles is about 75. In one embodiment, the number of cycles is about 100. In one embodiment, the number of cycles is about 125. In one embodiment, the number of cycles is about 150. In one embodiment, the number of cycles is about 175. In one embodiment, the number of cycles is about 200. In one embodiment, the number of cycles is about 225. In one embodiment, the number of cycles is about 250. In one embodiment, the number of cycles is about 275. In one embodiment, the number of cycles is about 300. In one embodiment, the number of cycles is about 325. In one embodiment, the number of cycles is about 350. In one embodiment, the number of cycles is about 400. In one embodiment, the number of cycles is about 450. In one embodiment, the number of cycles is about 500. In one embodiment, the number of cycles is about 750. In one embodiment, the number of cycles is about 1000.

Steps (i) through (vi) of the disclosed and claimed processes are described in more detail as follows.

### Step (i) First Surface Modification

In the step (i) first surface modification, at least one fluorinating agent is used to convert a surface including, consisting essentially of or consisting of one or more metal oxide (e.g., ZrO₂, HfO₂, HfₓZr₁₋ₓO₂ where x is a value between 0 and 1, and other materials based on ZrO₂ and HfO₂ with engineered impurities or dopants) into the corresponding fluorinated species and thereby producing a fluorinated metal surface. In this step, the one or more metal oxide is exposed to the fluorinating agent for a period of time before moving to step (ii).

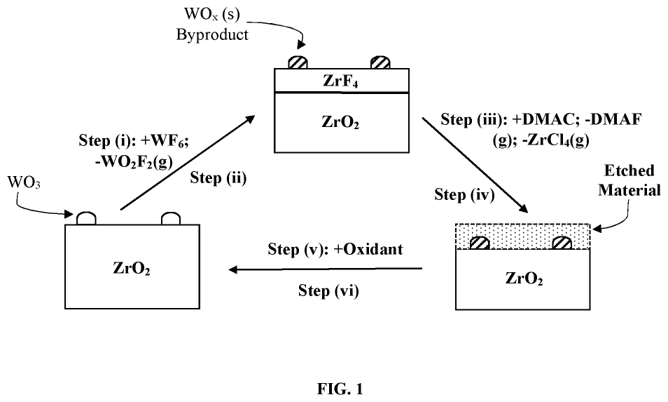

As those skilled in the art will understand, the initial exposure (not shown in FIG. 1) of the metal oxide surface to the fluorinating agent will produce by-products on the surface (e.g., use of WF₆ as the fluorinating agent will result in W species (e.g., WOₓ, where x is between 2 and 3)) that contaminate the surface and that will, over time, slow down or halt the etching process. Accordingly, the disclosed and claimed processes include a step (v) in which such species are oxidized to species that can be readily volatilized upon exposure to the fluorinating agent when step (i) is repeated during the next cycle.

### (a) Metal Oxides

The metal oxide includes any acceptable and/or desirable metal oxide. In one embodiment, the metal oxide includes one or more of ZrO₂, HfO₂, HfₓZr₁₋ₓO₂ where x is a value between 0 and 1, other materials based on ZrO₂ and HfO₂ with engineered impurities or dopants, TiO₂, Al₂O₃ and combinations thereof. In one aspect of this embodiment, the metal oxide includes ZrO₂. In one aspect of this embodiment, the metal oxide includes HfO₂. In one aspect of this embodiment, the metal oxide includes HfₓZr₁₋ₓO₂ where x is a value between 0 and 1. In one aspect of this specific embodiment, m=0.1. In one aspect of this specific embodiment, m=0.2. In one aspect of this specific embodiment, m=0.3. In one aspect of this specific embodiment, m=0.4. In one aspect of this specific embodiment, m=0.5. In one aspect of this specific embodiment, m=0.6. In one aspect of this specific embodiment, m=0.7. In one aspect of this specific embodiment, m=0.8. In one aspect of this specific embodiment, m=0.9. In one aspect of this specific embodiment, m=0.95. In one aspect of this embodiment, the metal oxide includes materials based on ZrO₂ and HfO₂ with engineered impurities. In one aspect of this embodiment, the metal oxide includes TiO₂. In one aspect of this embodiment, the metal oxide includes Al₂O₃.

### (b) Fluorinating Agents

The fluorinating agent includes one or more metal fluoride. In one aspect of this embodiment, the one or more metal fluoride is one or more of VF₅, NbF₅, TaF₅, MoF₆, WF₆, ReF₆ and ReF₇. In one aspect of this embodiment, the one or more metal fluoride includes VF₅. In one aspect of this embodiment, the one or more metal fluoride includes NbF₅. In one aspect of this embodiment, the one or more metal fluoride includes TaF₅. In one aspect of this embodiment, the one or more metal fluoride includes MoF₆. In one aspect of this embodiment, the one or more metal fluoride includes WF₆. In one aspect of this embodiment, the one or more metal fluoride includes ReF₆. In one aspect of this embodiment, the one or more metal fluoride includes ReF₇.

The fluorinating agent could alternatively or additionally include one or more semimetal fluoride. In one aspect of this embodiment, the one or more semimetal fluoride is one or more of AsF₅, SbF₅, and TeF₆. In one aspect of this embodiment, the one or more metal fluoride includes AsF₅. In one aspect of this embodiment, the one or more metal fluoride includes SbF₅. In one aspect of this embodiment, the one or more metal fluoride includes TeF₆.

The fluorinating agent could alternatively or additionally include one or more metal-free or semimetal-free fluorinating agent, e.g., one or more of anhydrous HF, HF-pyridine, XeF₂, SF₄ and combinations thereof. Thus, in one embodiment, the fluorinating agent includes one or more non-metal or non-semimetal fluoride. Although these metal-free and semimetal-free fluorinating agents are considered to part of the disclosed and claimed subject matter, these materials are generally not preferred for use in the disclosed and claimed processes since they are very highly corrosive. Thus, in another embodiment, the fluorinating agent is substantially free of non-metal or non-semimetal fluorides. In another embodiment, the fluorinating agent is free of non-metal or non-semimetal fluorides.

### (c) Conditions

### Time

As noted above, in step (i), the one or more metal oxide is exposed to the fluorinating agent for a period of time (“exposure time”) before moving to step (ii). In one embodiment, the step (i) first surface modification exposure time is from about 0.5 seconds to about 30 seconds. In one embodiment, the step (i) first surface modification exposure time is from about 0.5 seconds to about 10 seconds. In one embodiment, the step (i) first surface modification exposure time is from about 1 second to about 7 seconds. In one embodiment, the step (i) first surface modification exposure time is from about 7 seconds to about 10 seconds. In one embodiment, the step (i) first surface modification exposure time is from about 10 seconds to about 20 seconds. In one embodiment, the step (i) first surface modification exposure time is from about 20 seconds to about 30 seconds. In one embodiment, the step (i) first surface modification exposure time is about 0.25 seconds. In one embodiment, the step (i) first surface modification exposure time is about 0.5 seconds. In one embodiment, the step (i) first surface modification exposure time is about 1 second. In one embodiment, the step (i) first surface modification exposure time is about 2 seconds. In one embodiment, the step (i) first surface modification exposure time is about 3 seconds. In one embodiment, the step (i) first surface modification exposure time is about 4 seconds. In one embodiment, the step (i) first surface modification exposure time is about 5 seconds. In one embodiment, the step (i) first surface modification exposure time is about 6 seconds. In one embodiment, the step (i) first surface modification exposure time is about 7 seconds. In one embodiment, the step (i) first surface modification exposure time is about 8 seconds. In one embodiment, the step (i) first surface modification exposure time is about 9 seconds. In one embodiment, the step (i) first surface modification exposure time is about 10 seconds. In one embodiment, the step (i) first surface modification exposure time is about 12 seconds. In one embodiment, the step (i) first surface modification exposure time exposure is about 15 seconds. In one embodiment, the step (i) first surface modification exposure time is about 17 seconds. In one embodiment, the step (i) first surface modification exposure time is about 20 seconds. In one embodiment, the step (i) first surface modification exposure time is about 25 seconds. In one embodiment, the step (i) first surface modification exposure time is about 30 seconds.

### Flow Rate of Fluorinating Agent

In one embodiment, the fluorinating agent is flowed at from about 5 sccm to about 500 sccm. In one embodiment, the fluorinating agent is flowed at from about 0.5 sccm to about 100 sccm. In one embodiment, the fluorinating agent is flowed at from about 1 sccm to about 200 sccm. In one embodiment, the fluorinating agent is flowed at from about 1 sccm to about 100 sccm. In one embodiment, the fluorinating agent is flowed at from about 1 sccm to about 50 sccm. In one embodiment, the fluorinating agent is flowed at from about 5 sccm to about 25 sccm. In one embodiment, the fluorinating agent is flowed at from about 10 sccm to about 20 sccm. In one embodiment, the fluorinating agent is flowed at from about 15 sccm to about 25 sccm. In one embodiment, the fluorinating agent is flowed at about 5 sccm. In one embodiment, the fluorinating agent is flowed at about 10 sccm. In one embodiment, the fluorinating agent is flowed at about 15 sccm. In one embodiment, the fluorinating agent is flowed at about 20 sccm. In one embodiment, the fluorinating agent is flowed at about 25 sccm. In one embodiment, the fluorinating agent is flowed at about 30 sccm. In one embodiment, the fluorinating agent is flowed at about 35 sccm. In one embodiment, the fluorinating agent is flowed at about 40 sccm. In one embodiment, the fluorinating agent is flowed at about 45 sccm. In one embodiment, the fluorinating agent is flowed at about 50 sccm. In one embodiment, the fluorinating agent is flowed at about 60 sccm. In one embodiment, the fluorinating agent is flowed at about 70 sccm. In one embodiment, the fluorinating agent is flowed at about 80 sccm. In one embodiment, the fluorinating agent is flowed at about 90 sccm. In one embodiment, the fluorinating agent is flowed at about 100 sccm. In one embodiment, the fluorinating agent is flowed at about 125 sccm. In one embodiment, the fluorinating agent is flowed at about 150 sccm. In one embodiment, the fluorinating agent is flowed at about 200 sccm. In one embodiment, the fluorinating agent is flowed at about 250 sccm. In one embodiment, the fluorinating agent is flowed at about 300 sccm. In one embodiment, the fluorinating agent is flowed at about 350 sccm. In one embodiment, the fluorinating agent is flowed at about 400 sccm. In one embodiment, the fluorinating agent is flowed at about 450 sccm. In one embodiment, the fluorinating agent is flowed at about 500 sccm.

In one embodiment, the fluorinating agent is supplied alone.

In one embodiment, the fluorinating agent is supplied with a suitable carrier gas. In one embodiment, the carrier gas includes argon. In one embodiment, the carrier gas includes nitrogen.

### Pressure

The step (i) first surface modification can be carried out at any suitable chamber pressure. In one embodiment, the pressure is from about 0.5 torr to about 100 torr. The step (i) first surface modification can be carried out at any suitable chamber pressure. In one embodiment, the pressure is from about 5 torr to about 100 torr. In one embodiment, the pressure is from about 0.5 torr to about 15 torr. In one embodiment, the pressure is from about 1 torr to about 12 torr. In one embodiment, the pressure is from about 1 torr to about 10 torr. In one embodiment, the pressure is from about 1 torr to about 5 torr. In one embodiment, the pressure is from about 1 torr to about 2 torr. In one embodiment, the pressure is from about 0.5 torr to about 5 torr. In one embodiment, the pressure is from about 0.2 torr to about 2 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### (d) Exemplary Step (i)

In an exemplary embodiment of the step (i) first surface modification, and as illustrated in FIG. 1, a ZrO₂ surface is exposed to tungsten hexafluoride (WF₆) thereby converting the solid ZrO₂ to solid ZrF₄ (i.e., ZrO₂ (s)+WF₆ (g)-->ZrF₄ (s)+WO₂F₂ (g)). In one aspect of the exemplary embodiment, and as noted above, this step may introduce some W residues/byproducts.

### Step (ii) First Purge

In the step (ii) first purge, any suitable inert purge gas can be used. In one embodiment, the purge gas includes argon. In one embodiment, the purge gas includes nitrogen.

### Time

In one embodiment, the step (ii) first purge time is from about 0.5 seconds to about 30 seconds. In one embodiment, the step (ii) first purge time is from about 0.5 seconds to about 10 seconds. In one embodiment, the step (ii) first purge time is from about 1 second to about 7 seconds. In one embodiment, the step (ii) first purge time is from about 7 seconds to about 10 seconds. In one embodiment, the step (ii) first purge time is from about 10 seconds to about 20 seconds. In one embodiment, the step (ii) first purge time is from about 20 seconds to about 30 seconds. In one embodiment, the step (ii) first purge time is from about 30 seconds to about 60 seconds. In one embodiment, the step (ii) first purge time is about 0.25 seconds. In one embodiment, the step (ii) first purge time is about 0.5 seconds. In one embodiment, the step (ii) first purge time is about 1 second. In one embodiment, the step (ii) first purge time is about 2 seconds. In one embodiment, the step (ii) first purge time is about 3 seconds. In one embodiment, the step (ii) first purge time is about 4 seconds. In one embodiment, the step (ii) first purge time is about 5 seconds. In one embodiment, the step (ii) first purge time is about 6 seconds. In one embodiment, the step (ii) first purge time is about 7 seconds. In one embodiment, the step (ii) first purge time is about 8 seconds. In one embodiment, the step (ii) first purge time is about 9 seconds. In one embodiment, the step (ii) first purge time is about 10 seconds. In one embodiment, the step (ii) first purge time is about 12 seconds. In one embodiment, the step (ii) first purge time exposure is about 15 seconds. In one embodiment, the step (ii) first purge time is about 17 seconds. In one embodiment, the step (ii) first purge time is about 20 seconds. In one embodiment, the step (ii) first purge time is about 25 seconds. In one embodiment, the step (ii) first purge time is about 30 seconds. In one embodiment, the step (ii) first purge time is about 35 seconds. In one embodiment, the step (ii) first purge time is about 40 seconds. In one embodiment, the step (ii) first purge time is about 50 seconds. In one embodiment, the step (ii) first purge time is about 60 seconds.

### Flow Rate

In one embodiment, the first purge gas is flowed at from about 100 sccm to about 5000 sccm. In one embodiment, the first purge gas is flowed at from about 500 sccm to about 2500 sccm. In one embodiment, the first purge gas is flowed at from about 1000 sccm to about 2000 sccm. In one embodiment, the first purge gas is flowed at about 100 sccm. In one embodiment, the first purge gas is flowed at about 200 sccm. In one embodiment, the first purge gas is flowed at about 300 sccm. In one embodiment, the first purge gas is flowed at about 400 sccm. In one embodiment, the first purge gas is flowed at about 500 sccm. In one embodiment, the first purge gas is flowed at about 1000 sccm. In one embodiment, the first purge gas is flowed at about 1500 sccm. In one embodiment, the first purge gas is flowed at about 2000 sccm. In one embodiment, the first purge gas is flowed at about 2500 sccm. In one embodiment, the first purge gas is flowed at about 3000 sccm. In one embodiment, the first purge gas is flowed at about 3500 sccm. In one embodiment, the first purge gas is flowed at about 4000 sccm. In one embodiment, the first purge gas is flowed at about 4500 sccm. In one embodiment, the first purge gas is flowed at about 5000 sccm.

### Pressure

The step (ii) first purge step can be carried out at any suitable chamber pressure. In one embodiment, the pressure is from about 0.05 torr to about 5 torr. In one embodiment, the pressure is from about 1 torr to about 5 torr. In one embodiment, the pressure is from about 1 torr to about 2 torr. In one embodiment, the pressure is between about 0.5 torr to about 5 torr. In one embodiment, the pressure is from about 0.05 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr.

Step (iii) Ligand-Exchange

In the step (iii) ligand-exchange, the fluorinated metal surface is exposed to one or more chlorine ligand-supplying agent for a period of time sufficient to replace (i.e., exchange) the fluorine ions with chlorine and to produce a volatile chlorinated metal species.

### (a) Ligands

The chlorine ligand-supplying agent includes one or more chlorine ligand-supplying agents capable of exchanging fluoride ions with chloride ions. In one aspect of this embodiment, the one or more chlorine ligand-supplying agent includes one or more of dimethylaluminum chloride (DMAC, Al(CH₃)₂Cl), diethylaluminum chloride (DEAC, Al(C₂H₅)₂Cl), titanium tetrachloride (TiCl₄) boron trichloride (BCl₃) and combinations thereof. In one aspect of this embodiment, the one or more chlorine ligand-supplying agent includes DMAC. In one aspect of this embodiment, the one or more chlorine ligand-supplying agent includes DEAC. In one aspect of this embodiment, the one or more chlorine ligand-supplying agent includes TiCl₄. In one aspect of this embodiment, the one or more chlorine ligand-supplying agent includes BCl₃. In one aspect of this embodiment, the one or more chlorine ligand-supplying agent includes a combination of two or more of DMAC, DEAC, TiCl₄ and BCl₃. As those skilled in the art will recognize, DMAC, DEAC, and TiCl₄ are each considered non-corrosive chlorinators. In this regard, it is preferred that the chlorine ligand-supplying agent be a non-corrosive chlorinator such as DMAC, DEAC, and/or TiCl₄.

As those skilled in the art will recognize, however, the chlorine ligand-supplying agent could alternatively or additionally include one or more stronger/more corrosive chlorinator such as chlorine (Cl₂), boron trichloride (BCl₃), or thionyl chloride (SOCl₂). Although the use of more corrosive chlorine ligand-supplying agents is considered to be part of the disclosed and claimed subject matter, these materials are generally not preferred for use in the disclosed and claimed processes due to their corrosiveness. Thus, in another embodiment, the chlorinating agent is substantially free of corrosive chlorine ligand-supplying agents. In another embodiment, the chlorinating agent is substantially free of Cl₂. In another embodiment, the chlorinating agent is substantially free of BCl₃. In another embodiment, the chlorinating agent is substantially free of SOCl₂. In another embodiment, the chlorinating agent is free of corrosive chlorine ligand-supplying agents. In another embodiment, the chlorinating agent is free of Cl₂. In another embodiment, the chlorinating agent is free of BCl₃. In another embodiment, the chlorinating agent is free of SOCl₂.

### (b) Conditions

### Time

In one embodiment, the step (iii) ligand-exchange time is from about 0.5 seconds to about 30 seconds. In one embodiment, the step (iii) ligand-exchange time is from about 0.5 seconds to about 10 seconds. In one embodiment, the step (iii) ligand-exchange time is from about 1 second to about 7 seconds. In one embodiment, the step (iii) ligand-exchange time is from about 7 seconds to about 10 seconds. In one embodiment, the step (iii) ligand-exchange time is from about 10 seconds to about 20 seconds. In one embodiment, the step (iii) ligand-exchange time is from about 20 seconds to about 30 seconds. In one embodiment, the step (iii) ligand-exchange time is about 0.25 seconds. In one embodiment, the step (iii) ligand-exchange time is about 0.5 seconds. In one embodiment, the step (iii) ligand-exchange time is about 1 second. In one embodiment, the step (iii) ligand-exchange time is about 2 seconds. In one embodiment, the step (iii) ligand-exchange time is about 3 seconds. In one embodiment, the step (iii) ligand-exchange time is about 4 seconds. In one embodiment, the step (iii) ligand-exchange time is about 5 seconds. In one embodiment, the step (iii) ligand-exchange time is about 6 seconds. In one embodiment, the step (iii) ligand-exchange time is about 7 seconds. In one embodiment, the step (iii) ligand-exchange time is about 8 seconds. In one embodiment, the step (iii) ligand-exchange time is about 9 seconds. In one embodiment, the step (iii) ligand-exchange time is about 10 seconds. In one embodiment, the step (iii) ligand-exchange time is about 12 seconds. In one embodiment, the step (iii) ligand-exchange time exposure is about 15 seconds. In one embodiment, the step (iii) ligand-exchange time is about 17 seconds. In one embodiment, the step (iii) ligand-exchange time is about 20 seconds. In one embodiment, the step (iii) ligand-exchange time is about 25 seconds. In one embodiment, the step (iii) ligand-exchange time is about 30 seconds.

### Flow Rate of Ligand-Exchange Agent

In one embodiment, the ligand-exchange agent is flowed at from about 1 sccm to about 500 sccm. In one embodiment, the ligand-exchange agent is flowed at from about 5 sccm to about 500 sccm. In one embodiment, the ligand-exchange agent is flowed at from about 0.5 sccm to about 100 sccm. In one embodiment, the ligand-exchange agent is flowed at from about 1 sccm to about 50 sccm. In one embodiment, the ligand-exchange agent is flowed at from about 5 sccm to about 25 sccm. In one embodiment, the ligand-exchange agent is flowed at from about 10 sccm to about 20 sccm. In one embodiment, the ligand-exchange agent is flowed at from about 15 sccm to about 25 sccm. In one embodiment, the ligand-exchange agent is flowed at about 5 sccm. In one embodiment, the ligand-exchange agent is flowed at about 10 sccm. In one embodiment, the ligand-exchange agent is flowed at about 15 sccm. In one embodiment, the ligand-exchange agent is flowed at about 20 sccm. In one embodiment, the ligand-exchange agent is flowed at about 25 sccm. In one embodiment, the ligand-exchange agent is flowed at about 30 sccm. In one embodiment, the ligand-exchange agent is flowed at about 35 sccm. In one embodiment, the ligand-exchange agent is flowed at about 40 sccm. In one embodiment, the ligand-exchange agent is flowed at about 45 sccm. In one embodiment, the ligand-exchange agent is flowed at about 50 sccm. In one embodiment, the ligand-exchange agent is flowed at about 60 sccm. In one embodiment, the ligand-exchange agent is flowed at about 70 sccm. In one embodiment, the ligand-exchange agent is flowed at about 80 sccm. In one embodiment, the ligand-exchange agent is flowed at about 90 sccm. In one embodiment, the ligand-exchange agent is flowed at about 100 sccm. In one embodiment, the ligand-exchange agent is flowed at about 125 sccm. In one embodiment, the ligand-exchange agent is flowed at about 150 sccm. In one embodiment, the ligand-exchange agent is flowed at about 200 sccm. In one embodiment, the ligand-exchange agent is flowed at about 250 sccm. In one embodiment, the ligand-exchange agent is flowed at about 300 sccm. In one embodiment, the ligand-exchange agent is flowed at about 350 sccm. In one embodiment, the ligand-exchange agent is flowed at about 400 sccm. In one embodiment, the ligand-exchange agent is flowed at about 450 sccm. In one embodiment, the ligand-exchange agent is flowed at about 500 sccm.

In one embodiment, the ligand-exchange agent is supplied alone.

In one embodiment, the ligand-exchange agent is supplied with a suitable carrier gas. In one embodiment, the carrier gas includes argon. In one embodiment, the carrier gas includes nitrogen.

### Pressure

The step (iii) ligand-exchange can be carried out at any suitable chamber pressure. In one embodiment, the pressure is from about 0.5 torr to about 100 torr. The step (iii) ligand-exchange can be carried out at any suitable chamber pressure. In one embodiment, the pressure is from about 5 torr to about 100 torr. In one embodiment, the pressure is from about 0.5 torr to about 15 torr. In one embodiment, the pressure is from about 1 torr to about 12 torr. In one embodiment, the pressure is from about 1 torr to about 10 torr. In one embodiment, the pressure is from about 1 torr to about 5 torr. In one embodiment, the pressure is from about 1 torr to about 2 torr. In one embodiment, the pressure is from about 0.5 torr to about 5 torr. In one embodiment, the pressure is from about 0.2 torr to about 2 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

(d) Exemplary Step (iii)

In an exemplary embodiment of the step (iii) ligand-exchange, and as illustrated in FIG. 1, a layer of ZrF₄ atop the surface of ZrO₂ (as described above) undergoes ligand exchange with dimethylaluminum chloride (DMAC, Al(CH₃)₂Cl) to produce volatile ZrCl₄ and dimethylaluminum fluoride (DMAF, Al(CH₃)₂F) (i.e., ZrF₄ (s)+4Al(CH₃)₂Cl (g)-->ZrCl₄ (g)+4Al(CH₃)₂F (g)).

### Step (iv) Second Purge

In the step (iv) second purge, any suitable inert purge gas can be used. In one embodiment, the purge gas includes argon. In one embodiment, the purge gas includes nitrogen.

### Time

In one embodiment, the step (iv) second purge time is from about 0.5 seconds to about 30 seconds. In one embodiment, the step (iv) second purge time is from about 0.5 seconds to about 10 seconds. In one embodiment, the step (iv) second purge time is from about 1 second to about 7 seconds. In one embodiment, the step (iv) second purge time is from about 7 seconds to about 10 seconds. In one embodiment, the step (iv) second purge time is from about 10 seconds to about 20 seconds. In one embodiment, the step (iv) second purge time is from about 20 seconds to about 30 seconds. In one embodiment, the step (iv) second purge time is from about 30 seconds to about 60 seconds. In one embodiment, the step (iv) second purge time is about 0.25 seconds. In one embodiment, the step (iv) second purge time is about 0.5 seconds. In one embodiment, the step (iv) second purge time is about 1 second. In one embodiment, the step (iv) second purge time is about 2 seconds. In one embodiment, the step (iv) second purge time is about 3 seconds. In one embodiment, the step (iv) second purge time is about 4 seconds. In one embodiment, the step (iv) second purge time is about 5 seconds. In one embodiment, the step (iv) second purge time is about 6 seconds. In one embodiment, the step (iv) second purge time is about 7 seconds. In one embodiment, the step (iv) second purge time is about 8 seconds. In one embodiment, the step (iv) second purge time is about 9 seconds. In one embodiment, the step (iv) second purge time is about 10 seconds. In one embodiment, the step (iv) second purge time is about 12 seconds. In one embodiment, the step (iv) second purge time exposure is about 15 seconds. In one embodiment, the step (iv) second purge time is about 17 seconds. In one embodiment, the step (iv) second purge time is about 20 seconds. In one embodiment, the step (iv) second purge time is about 25 seconds. In one embodiment, the step (iv) second purge time is about 30 seconds. In one embodiment, the step (iv) second purge time is about 35 seconds. In one embodiment, the step (iv) second purge time is about 40 seconds. In one embodiment, the step (iv) second purge time is about 50 seconds. In one embodiment, the step (iv) second purge time is about 60 seconds.

### Flow Rate

In one embodiment, the second purge gas is flowed at from about 100 sccm to about 5000 sccm. In one embodiment, the second purge gas is flowed at from about 500 sccm to about 2500 sccm. In one embodiment, the second purge gas is flowed at from about 1000 sccm to about 2000 sccm. In one embodiment, the second purge gas is flowed at about 100 sccm. In one embodiment, the second purge gas is flowed at about 200 sccm. In one embodiment, the second purge gas is flowed at about 300 sccm. In one embodiment, the second purge gas is flowed at about 400 sccm. In one embodiment, the second purge gas is flowed at about 500 sccm. In one embodiment, the second purge gas is flowed at about 1000 sccm. In one embodiment, the second purge gas is flowed at about 1500 sccm. In one embodiment, the second purge gas is flowed at about 2000 sccm. In one embodiment, the second purge gas is flowed at about 2500 sccm. In one embodiment, the second purge gas is flowed at about 3000 sccm. In one embodiment, the second purge gas is flowed at about 3500 sccm. In one embodiment, the second purge gas is flowed at about 4000 sccm. In one embodiment, the second purge gas is flowed at about 4500 sccm. In one embodiment, the second purge gas is flowed at about 5000 sccm.

### Pressure

The step (iv) second purge step can be carried out at any suitable chamber pressure. In one embodiment, the pressure is from about 0.05 torr to about 5 torr. In one embodiment, the pressure is from about 1 torr to about 5 torr. In one embodiment, the pressure is between about 1 torr to about 2 torr. In one embodiment, the pressure is between about 0.5 torr to about 5 torr. In one embodiment, the pressure is between about 0.05 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr.

### Step (v) Second Surface Modification

In the step (v) second surface modification, the etched metal oxide surface is exposed to one or more oxidant for a period of time sufficient to oxidize metal byproducts present on the etched metal surface into species that can be readily volatilized upon exposure to the fluorinating agent when step (i) is repeated during the next cycle. As noted above, for example, if WF₆ is used as the fluorinating agent it will result in W species (e.g., WOₓ, where x is between about 2 and about 3) that contaminate the surface and that will, over time, slow down or halt the etching process. The oxidation step converts those byproducts to WO₃ which can be readily reacted removed upon exposure to the fluorinating agent when step (i) is repeated during the next cycle.

In one embodiment, the one or more oxidant includes one or more of oxygen (O₂), ozone (O₃), nitric oxide (NO), water (H₂O) vapor, hydrogen peroxide (H₂O₂), oxygen plasma (O*), and combinations thereof. In one aspect of this embodiment, the one or more oxidant includes oxygen. In one aspect of this embodiment, the one or more oxidant includes ozone. In one aspect of this embodiment, the one or more oxidant includes nitric oxide. In one aspect of this embodiment, the one or more oxidant includes water vapor. In one aspect of this embodiment, the one or more oxidant includes hydrogen peroxide. In one aspect of this embodiment, the one or more oxidant includes oxygen and ozone. In one aspect of this embodiment, the one or more oxidant includes oxygen plasma. In one aspect of this embodiment, the one or more oxidant includes oxygen plasma. In one embodiment, the one or more oxidant is a vapor.

In one embodiment, the exposure of the etched metal oxide surface to the one or more oxidant includes the sequential exposure of a first oxidant followed by the exposure of second oxidant that is different than the first oxidant. In one aspect of this embodiment, the first oxidant is one of oxygen and ozone and the second oxidant is the other of oxygen and ozone.

### (b) Conditions

### Time

In one embodiment, the step (v) oxidant flow time is from about 0.5 seconds to about 30 seconds. In one embodiment, the step (v) oxidant flow time is from about 0.5 seconds to about 10 seconds. In one embodiment, the step (v) oxidant flow time is from about 1 second to about 7 seconds. In one embodiment, the step (v) oxidant flow time is from about 7 seconds to about 10 seconds. In one embodiment, the step (v) oxidant flow time is from about 10 seconds to about 20 seconds. In one embodiment, the step (v) oxidant flow time is from about 20 seconds to about 30 seconds. In one embodiment, the step (v) oxidant flow time is from about 30 seconds to about 60 seconds. In one embodiment, the step (v) oxidant flow time is from about 1 second to about 60 seconds. In one embodiment, the step (v) oxidant flow time is about 0.25 seconds. In one embodiment, the step (v) oxidant flow time is about 0.5 seconds. In one embodiment, the step (v) oxidant flow time is about 1 second. In one embodiment, the step (v) oxidant flow time is about 2 seconds. In one embodiment, the step (v) oxidant flow time is about 3 seconds. In one embodiment, the step (v) oxidant flow time is about 4 seconds. In one embodiment, the step (v) oxidant flow time is about 5 seconds. In one embodiment, the step (v) oxidant flow time is about 6 seconds. In one embodiment, the step (v) oxidant flow time is about 7 seconds. In one embodiment, the step (v) oxidant flow time is about 8 seconds. In one embodiment, the step (v) oxidant flow time is about 9 seconds. In one embodiment, the step (v) oxidant flow time is about 10 seconds. In one embodiment, the step (v) oxidant flow time is about 12 seconds. In one embodiment, the step (v) oxidant flow time exposure is about 15 seconds. In one embodiment, the step (v) oxidant flow time is about 17 seconds. In one embodiment, the step (v) oxidant flow time is about 20 seconds. In one embodiment, the step (v) oxidant flow time is about 25 seconds. In one embodiment, the step (v) oxidant flow time is about 30 seconds. In one embodiment, the step (v) oxidant flow time is about 35 seconds. In one embodiment, the step (v) oxidant flow time is about 40 seconds. In one embodiment, the step (v) oxidant flow time is about 50 seconds. In one embodiment, the step (v) oxidant flow time is about 60 seconds.

### Flow Rate

In one embodiment, the oxidant is flowed at from about 50 sccm to about 3000 sccm. In one embodiment, the oxidant is flowed at from about 10 sccm to about 1000 sccm. In one embodiment, the oxidant is flowed at from about 500 sccm to about 1000 sccm. In one embodiment, the oxidant is flowed at from about 1000 sccm to about 2000 sccm. In one embodiment, the oxidant is flowed at about 50 sccm. In one embodiment, the oxidant is flowed at about 75 sccm. In one embodiment, the oxidant is flowed at about 100 sccm. In one embodiment, the oxidant is flowed at about 200 sccm. In one embodiment, the oxidant is flowed at about 300 sccm. In one embodiment, the oxidant is flowed at about 400 sccm. In one embodiment, the oxidant is flowed at about 500 sccm. In one embodiment, the oxidant is flowed at about 1000 sccm. In one embodiment, the oxidant is flowed at about 1500 sccm. In one embodiment, the oxidant is flowed at about 2000 sccm. In one embodiment, the oxidant is flowed at about 2500 sccm. In one embodiment, the oxidant is flowed at about 3000 sccm.

In one embodiment, the oxidant is supplied alone.

In one embodiment, the oxidant is supplied with a suitable carrier gas. In one embodiment, the carrier gas includes argon. In one embodiment, the carrier gas includes nitrogen.

### Pressure

The step (v) oxidation step can be carried out at any suitable chamber pressure. In one embodiment, the pressure is from about 0.5 torr to about 100 torr. The step (v) oxidation step can be carried out at any suitable chamber pressure. In one embodiment, the pressure is from about 5 torr to about 100 torr. In one embodiment, the pressure is from about 0.5 torr to about 15 torr. In one embodiment, the pressure is from about 1 torr to about 12 torr. In one embodiment, the pressure is from about 1 torr to about 10 torr. In one embodiment, the pressure is from about 1 torr to about 5 torr. In one embodiment, the pressure is from about 1 torr to about 2 torr. In one embodiment, the pressure is from about 0.5 torr to about 5 torr. In one embodiment, the pressure is from about 0.2 torr to about 2 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### (d) Exemplary Step (v)

In an exemplary embodiment of the step (v) second surface modification, and as illustrated in FIG. 1, the etched metal oxide surface is exposed to an oxidant thereby converting surface W species, which may be partially oxidized, fluorinated, chlorinated, or methylated, to a more oxidized form of W, such as WO₃, where the oxidant may be O₂, O₃, oxygen plasma, nitric oxide, H₂O, or H₂O₂ (i.e., WOₓF_{y}Cl_{z}(CH₃)ₙ (s)+[O₂, O₃, O*, NO, H₂O, H₂O₂]-->WO₃ (s)).

### Step (vi) Third Purge

In the step (vi) third purge, any suitable inert purge gas can be used. In one embodiment, the purge gas includes argon. In one embodiment, the purge gas includes nitrogen.

### Time

In one embodiment, the step (vi) third purge time is from about 0.5 seconds to about 30 seconds. In one embodiment, the step (vi) third purge time is from about 0.5 seconds to about 10 seconds. In one embodiment, the step (vi) third purge time is from about 1 second to about 7 seconds. In one embodiment, the step (vi) third purge time is from about 7 seconds to about 10 seconds. In one embodiment, the step (vi) third purge time is from about 10 seconds to about 20 seconds. In one embodiment, the step (vi) third purge time is from about 20 seconds to about 30 seconds. In one embodiment, the step (vi) third purge time is from about 30 seconds to about 60 seconds. In one embodiment, the step (vi) third purge time is from about 60 seconds to about 120 seconds. In one embodiment, the step (vi) third purge time is about 0.25 seconds. In one embodiment, the step (vi) third purge time is about 0.5 seconds. In one embodiment, the step (vi) third purge time is about 1 second. In one embodiment, the step (vi) third purge time is about 2 seconds. In one embodiment, the step (vi) third purge time is about 3 seconds. In one embodiment, the step (vi) third purge time is about 4 seconds. In one embodiment, the step (vi) third purge time is about 5 seconds. In one embodiment, the step (vi) third purge time is about 6 seconds. In one embodiment, the step (vi) third purge time is about 7 seconds. In one embodiment, the step (vi) third purge time is about 8 seconds. In one embodiment, the step (vi) third purge time is about 9 seconds. In one embodiment, the step (vi) third purge time is about 10 seconds. In one embodiment, the step (vi) third purge time is about 12 seconds. In one embodiment, the step (vi) third purge time exposure is about 15 seconds. In one embodiment, the step (vi) third purge time is about 17 seconds. In one embodiment, the step (vi) third purge time is about 20 seconds. In one embodiment, the step (vi) third purge time is about 25 seconds. In one embodiment, the step (vi) third purge time is about 30 seconds. In one embodiment, the step (vi) third purge time is about 35 seconds. In one embodiment, the step (vi) third purge time is about 40 seconds. In one embodiment, the step (vi) third purge time is about 50 seconds. In one embodiment, the step (vi) third purge time is about 60 seconds. In one embodiment, the step (vi) third purge time is about 75 seconds. In one embodiment, the step (vi) third purge time is about 90 seconds. In one embodiment, the step (vi) third purge time is about 120 seconds.

### Flow Rate

In one embodiment, the third purge gas is flowed at from about 100 sccm to about 5000 sccm. In one embodiment, the third purge gas is flowed at from about 500 sccm to about 2500 sccm. In one embodiment, the third purge gas is flowed at from about 1000 sccm to about 2000 sccm. In one embodiment, the third purge gas is flowed at about 100 sccm. In one embodiment, the third purge gas is flowed at about 200 sccm. In one embodiment, the third purge gas is flowed at about 300 sccm. In one embodiment, the third purge gas is flowed at about 400 sccm. In one embodiment, the third purge gas is flowed at about 500 sccm. In one embodiment, the third purge gas is flowed at about 1000 sccm. In one embodiment, the third purge gas is flowed at about 1500 sccm. In one embodiment, the third purge gas is flowed at about 2000 sccm. In one embodiment, the third purge gas is flowed at about 2500 sccm. In one embodiment, the third purge gas is flowed at about 3000 sccm. In one embodiment, the third purge gas is flowed at about 3500 sccm. In one embodiment, the third purge gas is flowed at about 4000 sccm. In one embodiment, the third purge gas is flowed at about 4500 sccm. In one embodiment, the third purge gas is flowed at about 5000 sccm.

### Pressure

The step (vi) third purge step can be carried out at any suitable chamber pressure. In one embodiment, the pressure is from about 0.05 torr to 5 torr. In one embodiment, the pressure is from about 1 torr to about 5 torr. In one embodiment, the pressure is from about 1 torr to about 2 torr. In one embodiment, the pressure is from about 0.5 torr to about 5 torr. In one embodiment, the pressure is from about 0.05 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr.

### Post-ALE Treatment

As noted above, the disclosed and claimed processes can further include an optional step (vii) post-treatment to remove impurities remaining on the metal oxide surface following a number of cycles. In one aspect of this embodiment, the optional step (vii) post-treatment includes treatment of the metal oxide surface with one or more oxidant for a desired period of time (e.g., about 10 seconds to about 500 seconds). In one aspect of this embodiment, the optional step (vii) post-treatment includes treatment of the metal oxide surface with one or more of oxygen (O₂) and ozone (O₃) for a desired period of time (e.g., about 10 seconds to about 500 seconds). In one aspect of this embodiment, the optional step (vii) post-treatment includes treatment of the metal oxide surface with oxygen (O₂). In one aspect of this embodiment, the optional step (vii) post-treatment includes treatment of the metal oxide surface with ozone (03). Examples of optional step (vii) post-treatment are described below in the Examples.

### Chamber (Reactor) Temperatures

### Outer Heater

In one embodiment, the chamber outer heater is set at from about 100° C. to about 200° C. In one embodiment, the chamber outer heater is set at about 100° C. In one embodiment, the chamber outer heater is set at about 120° C. In one embodiment, the chamber outer heater is set at about 140° C. In one embodiment, the chamber outer heater is set at about 160° C. In one embodiment, the chamber outer heater is set at about 180° C. In one embodiment, the chamber outer heater is set at about 200° C.

### Lid Heater (i.e., Process Chamber Gas Delivery Zone)

In one embodiment, the chamber lid heater is set from about 100° C. to about 200° C. In one embodiment, the chamber lid heater is set at about 100° C. In one embodiment, the chamber lid heater is set at about 130° C. In one embodiment, the chamber lid heater is set at about 150° C. In one embodiment, the chamber lid heater is set at about 200° C.

### Inner Heater (i.e., Process Chamber or Sample Pedestal)

In one embodiment, the chamber inner heater is set at from about 100° C. to about 400° C. In one embodiment, the chamber inner heater is set at about 100° C. In one embodiment, the chamber inner heater is set at about 150° C. In one embodiment, the chamber inner heater is set at about 200° C. In one embodiment, the chamber inner heater is set at about 250° C. In one embodiment, the chamber inner heater is set at about 300° C. In one embodiment, the chamber inner heater is set at about 350° C. In one embodiment, the chamber inner heater is set at about 400° C.

### Film Properties

The disclosed and claimed subject matter further includes films prepared by the methods described herein.

### Film Aspect Ratio

In one embodiment, the films etched by the methods described herein have trenches, vias or other topographical features with an aspect ratio of about 0 to about 60. In a further aspect of this embodiment, the aspect ratio is about 1 to about 10. In a further aspect of this embodiment, the aspect ratio is about 10 to 100. In a further aspect of this embodiment, the aspect ratio is about 0. In a further aspect of this embodiment, the aspect ratio is about 1. In a further aspect of this embodiment, the aspect ratio is about 2. In a further aspect of this embodiment, the aspect ratio is about 5. In a further aspect of this embodiment, the aspect ratio is about 10. In a further aspect of this embodiment, the aspect ratio is about 20. In a further aspect of this embodiment, the aspect ratio is about 30. In a further aspect of this embodiment, the aspect ratio is about 40. In a further aspect of this embodiment, the aspect ratio is about 50. In a further aspect of this embodiment, the aspect ratio is about 60. In a further aspect of this embodiment, the aspect ratio is about 80. In a further aspect of this embodiment, the aspect ratio is about 100.

### Dielectric Constant

In another embodiment, the films etched by the methods described herein have a dielectric constant of between 5 and 10. In another embodiment, the films etched by the methods described herein have a dielectric constant of between 10 and 30. In another embodiment, the films etched by the methods described herein have a dielectric constant of between 30 and 50. In another embodiment, the films etched by the methods described herein have a dielectric constant of between 50 and 80. In another embodiment, the films etched by the methods described herein have a dielectric constant of about 1.5. In another embodiment, the films etched by the methods described herein have a dielectric constant of about 2. In another embodiment, the films etched by the methods described herein have a dielectric constant of about 3. In another embodiment, the films etched by the methods described herein have a dielectric constant of about 4. In another embodiment, the films etched by the methods described herein have a dielectric constant of about 5. In another embodiment, the films etched by the methods described herein have a dielectric constant of about 6. In another embodiment, the films etched by the methods described herein have a dielectric constant of about 7. In another embodiment, the films etched by the methods described herein have a dielectric constant of about 8. In another embodiment, the films etched by the methods described herein have a dielectric constant of about 9. In another embodiment, the films etched by the methods described herein have a dielectric constant of about 10. In another embodiment, the films etched by the methods described herein have a dielectric constant of about 12. In another embodiment, the films etched by the methods described herein have a dielectric constant of about 14. In another embodiment, the films etched by the methods described herein have a dielectric constant of about 16. In another embodiment, the films etched by the methods described herein have a dielectric constant of about 18. In another embodiment, the films etched by the methods described herein have a dielectric constant of about 20. In another embodiment, the films etched by the methods described herein have a dielectric constant of about 25. In another embodiment, the films etched by the methods described herein have a dielectric constant of about 30. In another embodiment, the films etched by the methods described herein have a dielectric constant of about 35. In another embodiment, the films etched by the methods described herein have a dielectric constant of about 40. In another embodiment, the films etched by the methods described herein have a dielectric constant of about 45. In another embodiment, the films etched by the methods described herein have a dielectric constant of about 50. In another embodiment, the films etched by the methods described herein have a dielectric constant of about 55. In another embodiment, the films etched by the methods described herein have a dielectric constant of about 60. In another embodiment, the films etched by the methods described herein have a dielectric constant of about 65. In another embodiment, the films etched by the methods described herein have a dielectric constant of about 70. In another embodiment, the films etched by the methods described herein have a dielectric constant of about 75. In another embodiment, the films etched by the methods described herein have a dielectric constant of about 80.

### Crystal Structure

In one embodiment, the films etched by the methods described herein are crystalline, with a desired crystal structure constituting the majority of the film, for example a cubic crystal structure, a tetragonal crystal structure, an orthorhombic crystal structure or a noncentrosymmetric crystal structure. In one embodiment, a cubic crystal structure constitutes the majority of a film composed of ZrO₂, HfO₂, a combination of HfO₂ and ZrO₂, or any of these materials with engineered impurities (i.e., dopants). In one embodiment, a tetragonal crystal structure constitutes the majority of a film composed of ZrO₂, HfO₂, a combination of HfO₂ and ZrO₂, or any of these materials with engineered impurities (i.e., dopants). In one embodiment, an orthorhombic crystal structure constitutes the majority of a film composed of ZrO₂, HfO₂, a combination of HfO₂ and ZrO₂, or any of these materials with engineered impurities (i.e., dopants). In one embodiment, a noncentrosymmetric crystal structure constitutes the majority of a film composed of ZrO₂, HfO₂, a combination of HfO₂ and ZrO₂, or any of these materials with engineered impurities (i.e., dopants). In one embodiment, a desired crystal structure constitutes about 50% to about 90% of the film. In one embodiment, a desired crystal structure constitutes about 90% to about 95% of the film. In one embodiment, a desired crystal structure constitutes about 95% to about 100% of the film.

### MIMcap Devices

In another aspect, the disclosed and claimed subject matter relates to a metal-insulator-metal capacitor (“MIMcap”) device including, consisting essentially of or consisting of a first electrode, a dielectric layer made using the disclosed and claimed ALE processes, and a second electrode. In a further aspect, the MIMcap devices ideally demonstrate a higher dielectric constant (k), which may also be expressed in terms of equivalent oxide thickness (EOT) of a silicon oxide dielectric layer to yield an equivalent capacitance, and lower leakage current than an otherwise equivalent MIMcap made without using the disclosed and claimed ALE processes.

In a further aspect, the first electrode and the second electrode are independently selected from TiN, W, Ni, Ru, Pt and Al.

In a further aspect, the first electrode and the second electrode are TiN. In a further aspect, the thickness of the starting dielectric layer prior to ALE is between about 5 nm and about 10 nm. In a further aspect, the thickness of the etched dielectric layer is between about 1 nm and about 6 nm. Another aspect is the use of a metal-containing film as disclosed and claimed or prepared by the method as disclosed and claimed as a dielectric layer in a metal-insulator-metal capacitor.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

In the following examples, ALE processes were conducted in an ALD system with a heated showerhead lid. This ALD system has capability to accommodate up to 12″ diameter wafer sizes. This ALD system has a heated pedestal upon which the wafer is disposed. For each experiment, a 44 mm×44 mm test substrate was disposed on a 300 mm silicon carrier wafer.

Dimethylaluminum chloride (DMAC) was obtained from EMD Electronics. The normal temperature of the DMAC source in all conditions is 35° C. DMAC was dosed in vapor draw mode for all experiments.

For each experiment, the pedestal was heated to a temperature 30 degrees C. higher than the intended sample temperature to accommodate for a temperature gradient across the carrier wafer. Throughout the entire process, an argon purge flow of 100 sccm was continuously run to protect sensitive interior parts of the chamber.

As shown in these Examples, the ALE process can be readily controlled (i.e., tailored) to provide a specific amount of etch for desired applications.

### Examples 1-3: Zirconium Oxide ALE Using DMAC, WF₆ and O₂

Test substrates were prepared by atomic layer deposition (ALD) of about 93-95 Å of zirconium oxide atop a 300 mm silicon wafer coated with about 50 Å of titanium nitride. The second 300 mm wafer was then cleaved into 44 mm×44 mm test substrates. Each test substrate was annealed at 500° C. for 10 minutes in Ar prior to etch.

ALE was performed with the process chamber pedestal heater set at either 280° C., 330° C. or 380° C. (corresponding to an estimated sample temperature of about 250° C., 300° C. or 350° C.) and the process chamber lid heaters set at 130° C. and the showerhead heater set at 140° C. over the course of 24 to 50 cycles with each cycle including one dose of DMAC (pre-heated at 35° C.), one dose of WF₆, and one dose of O₂ as follows:

| Step | Conditions |
|---|---|
| (i) | a 5-second exposure of 20 sccm of tungsten hexafluoride, WF₆ |
| | (delivered concurrently with 380 sccm of argon as a carrier gas), |
| | while the chamber pressure was maintained at 1.0 Torr |
| (ii) | a purge of about 30 seconds with about 2000 sccm of argon, |
| | while the chamber was pumped without maintaining a |
| | specific pressure |
| (iii) | a 2-second exposure of dimethylaluminum chloride, DMAC |
| | (delivered concurrently with 2000 |
| | sccm of argon as a carrier gas), |
| | while the chamber pressure was maintained at 1.0 Torr |
| (iv) | a purge of about 30 seconds with about 2000 sccm of argon, |
| | while the chamber was pumped without maintaining a |
| | specific pressure |
| (v) | a 15-second exposure of 800 sccm of oxygen, O₂, |
| | while the chamber pressure was maintained at 1.0 Torr |
| (vi) | a purge of about 30 seconds with about 2000 sccm of argon, |
| | while the chamber was pumped without |
| | maintaining a specific pressure |

After the process was complete, a surface treatment step of about 100 sccm ozone (O₃) with about 400 sccm oxygen (O₂) was performed for 60 seconds in the same chamber at the same pedestal temperature as the etch sequence.

The processes described in this Example removed ZrO₂ as specified in Table 1.

TABLE 1

| | | Temp | Amount of ZrO₂ |
|---|---|---|---|
| Example | Cycles | (° C.) | Etched (Å) |
| 1 | 50 | 280 | 3-8 |
| 2 | 24 | 330 | 13-17 |
| 3 | 24 | 380 | 23-27 |

### Example 4: Zirconium Oxide ALE Using DMAC, WF₆ and (O₂+O₃)

Test substrates were prepared by atomic layer deposition (ALD) of about 91-95 Å of zirconium oxide atop a second 300 mm silicon wafer coated with about 50 Å of titanium nitride. The second 300 mm wafer was then cleaved into 44 mm×44 mm test substrates. Each test substrate was annealed at 500° C. for 10 minutes in Ar prior to etch.

ALE was performed with the process chamber pedestal heater set 380° C. (corresponding to an estimated sample temperature of about 350° C.) and the process chamber lid heaters set at 130° C. and the showerhead heater set at 140° C. over the course of 24 cycles with each cycle including one dose of DMAC (pre-heated at 35° C.), one dose of WF₆, and one dose of a mixture of O₂ and O₃ as follows:

| Step | Conditions |
|---|---|
| (i) | a 5-second exposure of 20 sccm of tungsten hexafluoride, WF₆ |
| | (delivered concurrently with 380 sccm of argon as a carrier gas), |
| | while the chamber pressure was maintained at 1.0 Torr |
| (ii) | a purge of about 30 seconds with about 2000 sccm of argon, |
| | while the chamber was pumped without maintaining a |
| | specific pressure |
| (iii) | a 2-second exposure of dimethylaluminum chloride, DMAC |
| | (delivered concurrently with 2000 sccm of argon as a carrier gas), |
| | while the chamber pressure was maintained at 1.0 Torr |
| (iv) | a purge of about 30 seconds with about 2000 sccm of argon, |
| | while the chamber was pumped without maintaining a |
| | specific pressure |
| (v) | a 15-second exposure of about 32 sccm of ozone, O₃, mixed with |
| | about 768 sccm of oxygen, |
| | O₂, for a total oxidant flow of 800 sccm (4% O₃/96% O₂), |
| | while the chamber pressure was maintained at 1.0 Torr |
| (vi) | a purge of about 90 seconds with about 2000 sccm of argon, |
| | while the chamber was pumped without maintaining a |
| | specific pressure |

After the process was complete, a surface treatment step of about 20 sccm ozone (O₃) with about 480 sccm oxygen (O₂) was performed for 300 seconds in the same chamber at the same pedestal temperature as the etch sequence.

The process described in Example 4 removed 22-28 Å of ZrO₂.

### Example 5: Hafnium Oxide ALE Using DMAC, WF₆ and (O₂+O₃)

Test substrates were prepared by atomic layer deposition (ALD) of about 67-69 Å of hafnium oxide atop a second 300 mm silicon wafer. The second 300 mm wafer was then cleaved into 44 mm×44 mm test substrates.

ALE was performed with the process chamber pedestal heater set 400° C. (corresponding to an estimated sample temperature of about 370° C.) and the process chamber lid heaters set at 130° C. and the showerhead heater set at 140° C. over the course of 60 cycles with each cycle including one dose of DMAC (pre-heated at 35° C.), one dose of WF₆, and one dose of a mixture of O₂ and O₃ as follows:

| Step | Conditions |
|---|---|
| (i) | a 5-second exposure of 40 sccm of tungsten hexafluoride, WF₆ |
| | (delivered concurrently with 360 sccm of argon as a carrier gas), |
| | while the chamber pressure was maintained at 2.0 Torr |
| (ii) | a purge of about 30 seconds with about 2000 sccm of argon, |
| | while the chamber was pumped without maintaining a |
| | specific pressure |
| (iii) | a 2-second exposure of dimethylaluminum chloride, DMAC |
| | (delivered concurrently with 2000 sccm of argon as a carrier gas), |
| | while the chamber pressure was maintained at 2.0 Torr |
| (iv) | a purge of about 30 seconds with about 2000 sccm of argon, |
| | while the chamber was pumped without maintaining a |
| | specific pressure |
| (v) | a 15-second exposure of about 32 sccm of ozone, |
| | O₃, mixed with about 768 sccm of oxygen, |
| | O₂, for a total oxidant flow of 800 sccm (4% O₃/96% O₂), |
| | while the chamber pressure was maintained at 2.0 Torr |
| (vi) | a purge of about 90 seconds with about 2000 sccm of argon, |
| | while the chamber was pumped without maintaining a |
| | specific pressure |

After the process was complete, a surface treatment step of about 20 sccm ozone (O₃) with about 480 sccm oxygen (O₂) was performed for 300 seconds in the same chamber at the same pedestal temperature as the etch sequence.

The process described in Example 5 removed 25-29 Å of HfO₂.

### Example 6: (Hf,Zr)O₂ ALE Using DMAC, WF₆ and (O₂+O₃)

Test substrates were prepared by atomic layer deposition (ALD) of about 74-76 Å of Hf_{0.5}Zr_{.5} atop a second 300 mm silicon wafer. The second 300 mm wafer was then cleaved into 44 mm×44 mm test substrates.

ALE was performed with the process chamber pedestal heater set 400° C. (corresponding to an estimated sample temperature of about 370° C.) and the process chamber lid heaters set at 130° C. and the showerhead heater set at 140° C. over the course of 60 cycles with each cycle including one dose of DMAC (pre-heated at 35° C.), one dose of WF₆, and one dose of a mixture of O₂ and O₃ as follows:

| Step | Conditions |
|---|---|
| (i) | a 5-second exposure of 40 sccm of tungsten hexafluoride, WF₆ |
| | (delivered concurrently with 360 sccm of argon as a carrier gas), |
| | while the chamber pressure was maintained at 1.0 Torr |
| (ii) | a purge of about 30 seconds with about 2000 sccm of argon, |
| | while the chamber was pumped without maintaining a |
| | specific pressure |
| (iii) | a 2-second exposure of dimethylaluminum chloride, DMAC |
| | (delivered concurrently with 2000 sccm of argon as a carrier gas), |
| | while the chamber pressure was maintained at 1.0 Torr |
| (iv) | a purge of about 30 seconds with about 2000 sccm of argon, |
| | while the chamber was pumped without maintaining a |
| | specific pressure |
| (v) | a 15-second exposure of about 32 sccm of ozone, O₃, mixed |
| | with about 768 sccm of oxygen, O₂, for a total oxidant flow of |
| | 800 sccm (4% O₃/96% O₂), while the chamber pressure was |
| | maintained at 1.0 Torr |
| (vi) | a purge of about 90 seconds with about 2000 sccm of argon, |
| | while the chamber was pumped without maintaining a |
| | specific pressure |

After the process was complete, a surface treatment step of about 20 sccm ozone (03) with about 480 sccm oxygen (O₂) was performed for 300 seconds in the same chamber at the same pedestal temperature as the etch sequence.

The process described in Example 6 removed 16-20 Å of Hf_{0.5}Zr_{0.5}O₂.

### Examples 7-8: TiN/ZrO₂/TIN MIMcaps Prepared Using ZrO₂ ALE

Test substrates were prepared by atomic layer deposition (ALD) of zirconium oxide atop a second 300 mm silicon wafer coated with about 50 Å of titanium nitride. The second 300 mm wafer was then cleaved into 44 mm×44 mm test substrates. Each test substrate was annealed at 500° C. for 10 minutes in Ar prior to etch.

ALE was performed with the process chamber pedestal heater set 380° C. (corresponding to an estimated sample temperature of about 350° C.) and the process chamber lid heaters set at 130° C. and the showerhead heater set at 140° C. over the course of several cycles with each cycle including one dose of DMAC (pre-heated at 35° C.), one dose of WF₆, and one dose of a mixture of O₂ and O₃ as follows:

| Step | Conditions |
|---|---|
| (i) | a 5-second exposure of 20 sccm of tungsten hexafluoride, WF₆ |
| | (delivered concurrently with 380 sccm of argon as a carrier gas), |
| | while the chamber pressure was maintained at 1.0 Torr |
| (ii) | a purge of about 30 seconds with about 2000 sccm of argon, |
| | while the chamber was pumped without maintaining a |
| | specific pressure |
| (iii) | a 2-second exposure of dimethylaluminum chloride, DMAC |
| | (delivered concurrently with 2000 sccm of argon as a carrier gas), |
| | while the chamber pressure was maintained at 1.0 Torr |
| (iv) | a purge of about 30 seconds with about 2000 sccm of argon, |
| | while the chamber was pumped without maintaining a |
| | specific pressure |
| (v) | a 15-second exposure of about 32 sccm of ozone, |
| | O₃, mixed with about 768 sccm of oxygen, |
| | O₂, for a total oxidant flow of 800 sccm (4% O₃/96% O₂), |
| | while the chamber pressure was maintained at 1.0 Torr |
| (vi) | a purge of about 90 seconds with about 2000 sccm of argon, |
| | while the chamber was pumped without maintaining a |
| | specific pressure |

After the process was complete, a surface treatment step of about 20 sccm ozone (03) with about 480 sccm oxygen (O₂) was performed for 300 seconds in the same chamber at the same pedestal temperature as the etch sequence. To complete the MIMcap devices, titanium nitride top electrodes were deposited in a series of physical vapor deposition steps. Top electrode diameters ranged from about 250 μm to about 350 μm.

ZrO₂ thickness measurements and electrical device test results are given in Table 2. For the electrical results, median values from multiple tested devices are reported. EOT refers to the equivalent oxide thickness of silicon oxide which would provide equivalent dielectric performance to the measured MIMcap. In Example 7, use of the etch method described herein results in a MIMcap with lower leakage current and lower EOT relative to a comparison sample with the same ZrO₂ thickness. In Example 8, use of the etch method described herein results in a MIMcap with lower EOT but higher leakage current relative to a comparison sample with similar ZrO₂ thickness; however, it is generally expected that leakage current might increase as EOT decreases.

TABLE 2

| | Example | |
|---|---|---|
| | 7 | 8 |
| Pre-etch ZrO₂ thickness (Å) | 49-51 | 81-83 |
| Number of ALE cycles | 11 | 29 |
| Post-etch ZrO₂ thickness (Å) | 38-40 | 62-64 |
| Post-etch leakage current at −1 V (A/cm²) | 2.3*10⁻² | 1.0*10⁻⁵ |
| Post-etch EOT (nm) | 0.47 | 0.61 |
| Comparison sample ZrO₂ thickness (Å) | 38-40 | 59-61 |
| Comparison sample leakage | 6.2 × 10⁻² | 3.0 × 10⁻⁶ |
| current at −1 V (A/cm²) | | |
| Comparison sample EOT (nm) | 0.49 | 0.68 |

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A thermal ALE process for etching a surface of a metal oxide substrate comprising performing the steps of:
(i) a first surface modification comprising exposing the surface of the metal oxide substrate to one or more fluorinating agent to produce a fluorinated surface;
(ii) a first purge;
(iii) a ligand-exchange comprising exposing the fluorinated surface to one or more chlorine ligand-supplying agent to produce a volatile chlorinated species;
(iv) a second purge;
(v) a second surface modification comprising exposing the surface of the metal oxide substrate to one or more oxidants to oxidize metal byproducts; and
(vi) a third purge.

2. (canceled)

3. The process of claim 1, wherein the metal oxide comprises one or more of ZrO₂, HfO₂, HfₓZr₁₋ₓO₂ where x is a value between 0 and 1, TiO₂, Al₂O₃ ad and combinations thereof.

4-8. (canceled)

9. The process of claim 1, wherein the step (i) one or more fluorinating agent comprises one or more metal fluorides.

10. The process of claim 1, wherein the step (i) one or more fluorinating agent comprises one or more of VF₅, NbF₅, TaF₅, MoF₆, WF₆, ReF₆, ReF₇, AsF₅, SbF₅, and TeF₆.

11-21. (canceled)

22. The process of claim 1, wherein the step (i) exposure time of the one or more fluorinating agent to the surface of the metal oxide is from about 0.5 seconds to about 30 seconds.

23-31. (canceled)

32. The process of claim 1, wherein step (i) is carried out at a pressure from about 0.5 torr to about 100 torr.

33. The process of claim 1, wherein the step (iii) one or more chlorine ligand-supplying agent comprises one or more of dimethylaluminum chloride (DMAC; Al(CH₃)₂Cl), diethylaluminum chloride (DEAC; Al(C₂H₅)₂Cl), titanium tetrachloride (TiCl₄), boron trichloride (BCl₃) and combinations thereof.

34-37. (canceled)

38. The process of claim 1, wherein the step (iii) exposure time of the one or more chlorine ligand-supplying agent to the surface of the metal oxide is from about 0.5 seconds to about 30 seconds.

39-47. (canceled)

48. The process of claim 1, wherein step (iii) is carried out at a pressure from about 0.5 torr to about 100 torr.

49. The process of claim 1, wherein the step (v) one or more oxidants comprises one or more of oxygen (O₂), ozone (O₃), nitric oxide (NO), water (H₂O) vapor, hydrogen peroxide (H₂O₂), oxygen plasma (O*), and combinations thereof.

50-55. (canceled)

56. The process of claim 1, wherein the step (v) exposure time of the one or more oxidants is from about 1 second to about 60 seconds.

57-64. (canceled)

65. The process of claim 1, wherein step (v) is carried out at a pressure from about 0.5 torr to about 100 torr.

66-83. (canceled)

84. A metal-containing film etched by the process of claim 1, wherein the film comprises topographical features having an aspect ratio of about 0 to about 60.

85. (canceled)

86. A metal-containing film etched by the process of claim 1, wherein the film comprises topographical features having an aspect ratio of about 10 to about 100.

87-98. (canceled)

99. A metal-containing film etched by the process of claim 1, wherein the film has a dielectric constant of between about 1.5 to about 80.

100-129. (canceled)

130. A metal-containing film etched by the process of claim 1, wherein a majority of the film has a cubic crystal structure.

131. A metal-containing film etched by the process of claim 1, wherein a majority of the film has a tetragonal crystal structure.

132. A metal-containing film etched by the process of claim 1, wherein a majority of the film has an orthorhombic crystal structure.

133. A metal-containing film etched by the process of claim 1, wherein a majority of the film has a noncentrosymmetric crystal structure.

134. A metal-insulator-metal capacitor device comprising a first electrode, a dielectric layer and a second electrode, where the dielectric layer is made by the process of claim 1.

135. The metal-insulator-metal capacitor device of claim 134, wherein the dielectric layer has a thickness of between about 5 nm and about 10 nm before etching and a thickness of between about 1 nm and about 6 nm after etching.

136. (canceled)

137. The use of a metal-containing film etched by the process of claim 1 as a dielectric layer in a metal-insulator-metal capacitor.
